(19) United States
(12) Patent Application Publication
(10) Pub. No.: US 2016/0328090 A1
(43) Pub. Date: Nov. 10, 2016

(54) OLED DISPLAY PANEL

(71) Applicant: FLATFRONG LABORATORIES AB, Lund (SE)

(72) Inventor: Gunnar Klinghult, Lund (SE)

(21) Appl. No.: 15/112,069

(22) PCT Filed: Jan. 16, 2015
(86) PCT No.: PCT/SE2015/050042

§ 371 Date: Jul. 15, 2016

(30) Foreign Application Priority Data
Jan. 16, 2014 (SE) 1450036-7

(51) Int. Cl. G06F 3/042; H01L 27/32; H01L 51/52; G06F 3/041

(52) U.S. Cl. CPC G06F 3/0428; G06F 3/0416; H01L 27/322; H01L 27/323; H01L 51/5262; H01L 27/3218; H01L 51/5271; H01L 27/3213; G06F 2203/04109; H01L 2251/5369

(57) ABSTRACT

A display panel with a plurality of pixels, including a pixel of a first pixel configuration with a first sub-pixel, which comprises: a first OLED configured to emit light at a base wavelength, and a first quantum dot structure disposed over the first OLED, configured to absorb light of the base wavelength so as to emit light at a first longer wavelength. Embodiments include a touch-sensing display panel, where the first quantum dot structure is configured to emit IR light into a light guide having a front surface forming a touch-sensing region and an opposite rear surface facing the pixels, wherein said IR emitter is optically connected to emit light into the light guide for propagation therein through total internal reflection in at least the front surface; and an IR detector connected to receive propagated light from the light guide.

### CROSS-REFERENCE TO RELATED APPLICATIONS

The present application claims the benefit of Swedish patent application No. 1450036-7, filed 16 Jan. 2014.

### TECHNICAL FIELD

The present invention relates to display panels, and specifically to pixel structures for obtaining light of different wavelengths.

### BACKGROUND ART

While the early years of display technology were dominated by the cathode ray tube (CRT) technology, the first flat display panels were presented more than 50 years ago and dominate the market today. For television purposes, plasma type displays and Liquid Crystal Display (LCD) were the first to gain market share from CRT monitors. In recent years, a display technology that has grown to be a valid competitor to the LCD technology is based on the Organic Light Emitting Diode (OLED). The basic structure of an OLED is a cathode, which injects electrons, and an anode, and in between the two an organic emissive layer where electrons and electron holes re-combine under the emission of light. Modern OLED devices use many more layers in order to make them more efficient, but the basic functionality remains the same. OLED displays have the benefit over LCDs that there is no need for any backlight. There is thus less waste of light, and it is possible to obtain true black areas. However, there are also drawbacks related to the OLED technology. For one thing, the OLEDs tend to age, meaning that they degrade over time. More particularly, OLED materials used to produce blue light degrade significantly more rapidly than the materials that produce other colors, and therefore blue light output will decrease relative to the other colors of light. The result of this variation in the differential color output is that the color balance of the display may change. This can be partially avoided by adjusting color balance but this may require advanced control circuits and interaction with the user, which is unacceptable for some users.

### SUMMARY

It is an object of the invention to at least partly overcome one or more of the identified limitations of the prior art. This object, as well as further objects that may appear from the description below, are at least partly achieved by means of a display panel according to the independent claims, embodiments thereof being defined by the dependent claims.

A first aspect of the invention relates to a display panel with a plurality of pixels, including at least one pixel of a first pixel configuration with a first sub-pixel, which first sub-pixel comprises:

a first OLED configured to emit light at a base wavelength, and

a first quantum dot structure disposed over the first OLED, configured to absorb light of the base wavelength so as to emit light at a first longer wavelength.

In one embodiment the first OLED is configured to emit blue light and light at said first longer wavelength is red, said first pixel configuration further including a second sub-pixel, which comprises:

a second OLED configured to emit blue light, and

a second quantum dot structure disposed over the second OLED, configured to absorb blue light so as to emit green light; and a third sub-pixel, which comprises

a third OLED configured to emit blue light.

In one embodiment the display panel further comprises an IR emitter;

a light guide having a front surface forming a touch-sensing region and an opposite rear surface facing the pixels, wherein said IR emitter is optically connected to emit light into the light guide for propagation therein through total internal reflection in at least the front surface; and

an IR detector connected to receive propagated light from the light guide.

In one embodiment, said first pixel configuration further includes a sub-pixel configured to act as said IR emitter, which comprises:

a fourth OLED configured to emit blue light, and

a third quantum dot structure disposed over the fourth OLED, configured to absorb blue light so as to emit infrared light.

In one embodiment, a first sub-type of said first pixel configuration includes a sub-pixel configured to act as said IR emitter, which comprises:

a fourth OLED configured to emit blue light, and

a third quantum dot structure disposed over the fourth OLED, configured to absorb blue light so as to emit infrared light; and

wherein a second sub-type of said first pixel configuration includes a sub-pixel configured to act as said IR detector.

In one embodiment, light at said first longer wavelength is infrared such that said first sub-pixel is configured to act as an IR emitter, the display panel further comprising:

a light guide having a front surface forming a touch-sensing region and an opposite rear surface facing the pixels, wherein said IR emitter is optically connected to emit light into the light guide for propagation therein through total internal reflection in at least the front surface; and

an IR detector connected to receive propagated light from the light guide.

In one embodiment, the first OLED is configured to emit blue light, and said first pixel configuration further comprises:

a second sub-pixel including a second OLED configured to emit blue light;

a third sub-pixel including a third OLED configured to emit blue light;

wherein said first quantum dot structure is arranged over the first, second and third OLEDs and configured to absorb blue light so as to emit infrared light, such that the entire at least one pixel is configured to act as an IR emitter.

In one embodiment, the first OLED is configured to emit blue light, and said first pixel configuration further comprises:

a second sub-pixel including an OLED configured to emit green light;

a third sub-pixel including an OLED configured to emit red light; wherein said first quantum dot structure is arranged over the first, second and third sub-pixels and configured to absorb visible light so as to emit infrared light, such that the entire at least one pixel is configured to act as an IR emitter.

In one embodiment, the display panel comprises a control unit, configured to drive the first, second and third sub-pixels together, so as to act together as an IR emitter.

In one embodiment, said first sub-pixel is the only sub-pixel of said first pixel configuration.

In one embodiment, a number of pixels of the first pixel configuration are arranged in a peripheral region along at least one edge of the display panel, surrounding a central region of the display panel.

In one embodiment, the display panel comprises

an optical layer disposed at the rear surface of the light guide to cover the central region, wherein said optical layer is configured to reflect at least a part of the propagating light impinging thereon from within the light guide.

In one embodiment, said quantum dot structure configured to emit IR light is configured to have a higher refractive index than pixels disposed in the central region.

In one embodiment, a number of first type blocks, each including of one or more pixels of said first sub-type, are sequentially arranged with a number of second type blocks, each including of one or more pixels of said second sub-type, over said touch-sensing region.

In one embodiment, said IR emitter and said IR detector are configured to have higher refractive indices than the other sub-pixels of the respective pixel configuration.

In one embodiment, the display panel comprises a control unit, configured to drive the IR emitters of a first type block in synchronicity with the IR detectors of an adjacent second type block.

In one embodiment, comprising a control unit, the display panel comprises a control unit configured to drive a plurality of pixels in one first block as one common IR emitter.

In one embodiment, each quantum dot structure comprises:

a first layer, which is transparent to the wavelength of the light emitted from the OLED over which it is disposed, containing quantum dots; and

a second layer, disposed over the first layer, which is transparent to light emitted by said quantum dots but substantially opaque to light emitted from the OLED over which the first layer is disposed.

### BRIEF DESCRIPTION OF DRAWINGS

Embodiments of the invention will now be described in more detail with reference to the accompanying schematic drawings.

FIGS. 1A-1B show a top plan and a side view of a display panel with a plurality of pixels.

FIG. 2 illustrates one pixel including tri-chromatic sub-pixels of an embodiment of the display panel;

FIG. 3 illustrates the functional structure of the pixel configuration of FIG. 2.

FIG. 4 shows a schematic representation of a side section view of an embodiment of the pixel configuration according to one embodiment.

FIG. 5 schematically illustrates one sub-pixel according to an embodiment.

FIG. 6 side view of an object in contact with a light transmissive light guide to illustrated the use of FTIR for touch sensing.

FIG. 7 is a top plan view of an embodiment configured for touch sensing, with one activated emitter.

FIGS. 8A-8D illustrate side section views of different embodiments of an infrared (IR) emitter pixel.

FIG. 9A shows a side section view of an embodiment of the display panel.

FIG. 9B shows a perspective view of a cutout corner portion of the embodiment of FIG. 9A.

FIG. 10A is a top plan view of an embodiment of a pixel configuration of an alternative embodiment with an IR emitter.

FIG. 10B is a top plan view of an embodiment of a pixel configuration of an alternative embodiment with an IR detector.

FIG. 11A shows a schematic representation of a side section view of an embodiment of the pixel configuration according to FIG. 10A.

FIG. 11B shows a schematic representation of a side section view of an embodiment of the pixel configuration according to FIG. 10B.

one embodiments 9-10 are a side section views of other variants of the embodiment of FIG. 4.

FIG. 12 illustrates a top plan view of a portion of a display panel, in which pixels are sequentially arranged in blocks.

FIG. 13 schematically illustrates four blocks including a plurality of pixels, of a display panel embodiment as shown in FIG. 12.

### DETAILED DESCRIPTION OF EXAMPLE EMBODIMENTS

The present invention relates, in its broadest sense, to solutions for generating light of different wavelength ranges from an OLED display, by providing a pixel configuration incorporating a quantum dot structure. Various embodiment will be described on a functional level, sufficient for carrying out the claimed embodiments. However, the different ways of designing an OLED, including its detailed inner structure, is as such not crucial for the function or reproduction of the invention. Furthermore, the OLED technology is mature and well described in the art, and no detailed description of the OLED technology will hence be given herein. On a general level of description, though, an OLED comprises a rear electrode, e.g. an anode, and a front electrode, e.g. a cathode, and an intermediate organic structure formed by one or plural organic layers. The front electrode layer is transparent and may e.g. be made of indium tin oxide (no).

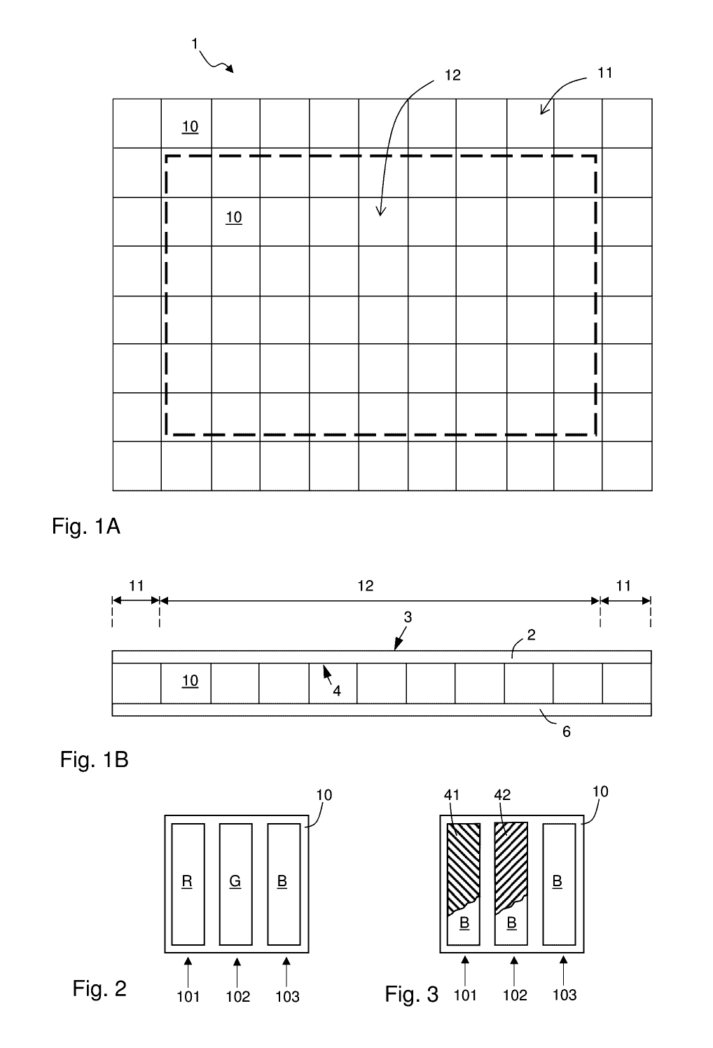

FIG. 1A schematically illustrates a top plan view of a display panel 1. The display panel 1 comprises a plurality of pixels 10, of which one or more may be configured in accordance with a first pixel configuration including different sub-pixels. The drawing shows a panel 1 with quite few pixels 10, but as the skilled person understands the pixel matrix of a display panel may include any number of pixels 10. Also, while the drawing illustrates a display panel 1 of a substantially rectangular shape, the panel 1 may in fact take any other surface shape, and may also be curved rather than planar. FIG. 1A also includes a dashed indication of a distinction between a peripheral region 11 along at least one edge of the display panel 1, and a central region 12. In the shown embodiment the peripheral region 11 is only one pixel wide, but in alternative embodiments the peripheral region 11 may comprise a band along one or more display edges with a width of two or more pixels.

FIG. 1B shows a side section view of the display panel 1 of FIG. 1A, schematically illustrating one row of pixels 10. The pixels 10 may be defined by patterning of the electrode layers and optionally by patterning of the organic structure. Different designs of a combined thin film transistor (TFT) structure and OLED pixels are shown in US20080150848, which is incorporated herein by reference. The display panel 1 comprises a backplane 6 and a transmissive cover lens 2. The cover lens 2 will also be referred to as a light guide 2 for certain embodiments below. The cover lens 2 may be included as a transparent substrate during manufacture of the display pixel matrix, e.g. as a backing for supporting the front electrode. Alternatively, the OLEDs may be built up from the side of the lower electrode layer on the backplane 6, and in that case the cover lens 2 is a cover that is nevertheless required for an OLED display, due to its sensitivity to moisture. The cover lens 2 has a front surface 3, and an opposite rear surface 4 facing the pixels 10. Although not shown in the drawings, the display panel 1 preferably also comprises a peripheral seal, to keep the organic layers free from moisture. While FIGS. 1A and 1B show the general layout of the display panel 1, the pixel configuration of various embodiments will now be discussed.

FIG. 2 shows a top plan view of one tri-chromatic pixel 10, including one or more sub-pixels 101, 102, 103. In an OLED display, different sub-pixels may be formed by selective doping to generate different light emissive properties of the different sub-pixels, e.g. such that the sub-pixels emit red light R, green light G, and blue light B, respectively. The pixel configuration of FIG. 2 is just one example of how to realize an RGB pixel 10, and is arranged in accordance with a traditional stripe configuration. For OLED display panels specifically, other configurations have been proposed, such as the PenTile type configurations used by Samsung in their AMOLED panels. In such a configuration, two red, two green, and one blue sub-pixel are included in one pixel. These and other potential specific pixel configurations will not be discussed herein in any further detail, and it should be noted that the present invention is applicable regardless of the exact layout of the pixel configuration.

The present invention is aimed at overcoming problems associated with state of the art OLED displays. More specifically, a pixel configuration is proposed, in which a first sub-pixel comprises a first OLED configured to emit light at a base wavelength, and a first quantum dot (QD) structure disposed over the first OLED, configured to absorb light of the base wavelength so as to emit light at a first longer wavelength.

As indicated by its name, a quantum dot is a nanocrystal e.g. made of semiconductor materials, small enough to display quantum mechanical properties.

Typical dots may be made from binary alloys such as cadmium selenide, cadmium sulfide, indium arsenide, and indium phosphide, or made from ternary alloys such as cadmium selenide sulfide. Some quantum dots may also comprise small regions of one material buried in another material with a larger band gap, so-called core-shell structures, e.g. with cadmium selenide in the core and zinc sulfide in the shell. A quantum dot can contain as few as 100 to 100000 atoms within the quantum dot volume, with a diameter of 10 to 50 atoms. This corresponds to about 2 to 10 nanometers.

Characteristics of quantum dots have been known since the early 1980s, and are well described in the art of nanophysics, and so are several known properties. One specific optical feature of quantum dots is the emission of photons under excitation, and the color of the emitted light. One photon absorbed by a quantum dot will yield luminescence, in terms of fluorescence, of one photon out. Due to the quantum confinement effect quantum dots of the same material, but with different sizes, can emit light of different colors. The larger the dot, the “redder” (lower energy) its fluorescence spectrum. Conversely, smaller dots emit “bluer” (higher energy) light. In other words, the bandgap energy that determines the energy, and hence color, of the fluorescent light is inversely proportional to the size of the quantum dot. The wavelength of the emitted light cannot be shorter than the wavelength of the absorbed light.

The ability to precisely control the size of a quantum dot enables manufacturers to determine the wavelength of the emission, which in turn determines the color of light the human eye perceives. The ability to control, or “tune” the emission from the quantum dot by changing its core size is called the “size quantisation effect”.

It has been acknowledged that quantum dots are interesting for use in displays, because they emit light in very specific Gaussian distributions. This can result in a display that more accurately renders the colors that the human eye can perceive. However, the discussion has been focused on backlight embodiments for LCDs. Traditionally, the backlight unit of a color LCD have been powered by fluorescent lamps or conventional white LEDs that are color filtered to produce red, green, and blue pixels. Improvements to the LCD technology have been suggested, which instead make use of a conventional blue-emitting LED as light source and converting part of the emitted light into pure green and red light by the appropriate quantum dots placed in front of the blue LED. This type of white light as backlight of an LCD unit allows for the better color gamut at lower cost than a RGB LED combination using three LEDs.

Different solutions for obtaining this effect have been suggested. QD Vision Inc. have developed a backlight solution that includes a thin transparent rod filled with a quantum dot composition. The rod is placed along one side of the backlight light guide, and is illuminated with blue light. The quantum dot composition will then shift, by its intrinsic fluorescence, part of the blue light to green and red light. Both unaffected blue light and shifted red and green light then gets coupled into the light guide of the backlight unit. The result is tri-chromatic (red, green and blue) white light.

Another way of making use of quantum dots in a backlight unit has been provided by Nanosys Inc together with 3M. Their suggestion is to replace the traditional diffuser film of a backlight unit with a film comprising quantum dots, a so-called Quantum Dot

Enhancement Film, or QDEF. Blue LEDs are used to inject light into a backlight light guide, and part of the blue light is then shifted to emit green and red in the QDEF to provide tri-chromatic white light.

Yet another attempt at introducing quantum dots in display technology has been proposed by Brown Elliott in US2012/091912, which also relates to a backlight structure for an LCD. In this proposal, quantum dots may be used in conjunction with blue OLEDs to obtain white light from the backlight unit.

Common for all these solutions is that color filtering must still be done above the LC layer. In the present invention, the QD structure is used in the active light-emitting pixel 10. Various embodiments related to this general pixel configuration will be described below, both where the first sub-pixel is one of several sub-pixels in one pixel, and where the first sub-pixel is the only sub-pixel. Also, it should be noted that this first pixel configuration may be applied to obtain a monochromatic pixel, which may be used together with e.g. tri-chromatic pixels of a second pixel configuration in various embodiments. Alternatively, the first pixel configuration may be used in pixels of two or more colors or wavelengths. Specifically, several embodiments will be described further below in conjunction with a touch-sensing display panel.

FIG. 3 illustrates the functional structure of the pixel configuration of FIG. 2 according to an embodiment of the invention. In this embodiment, the pixel 10 includes at least a first sub-pixel 101. The first sub-pixel 101, in turn, comprises a first OLED B configured to emit light at a base wavelength, but the sub-pixel 101 as such emits light at a first longer wavelength. In accordance with the invention, this is achieved by means of a first quantum dot (QD) structure 41 disposed over the first OLED B, configured to absorb light of the base wavelength so as to emit light at the first longer wavelength. In one specific embodiment, the first OLED B is configured to emit blue light and the first longer wavelength is red R. In this embodiment, the first pixel configuration further includes a second sub-pixel 102 which comprises a second blue light OLED B and a second QD structure 42 disposed over the second OLED configured to absorb blue light so as to emit green light. A third sub-pixel 103 comprises a third blue light OLED B.

By employing a pixel configuration in accordance with this embodiment, an RGB pixel 10 may be obtained comprising only one type of OLED, i.e. a blue OLED. While green and red OLEDs with high quantum efficiency tend to be more readily available than blue OLEDs today, the proposed embodiment alleviates problems associated with the fact that different color OLEDs tend to have different operating characteristics and, more particularly, that they age at different pace. The QD structures 41 and 42 could theoretically absorb each blue light photon to emit a red or green photon, respectively, but some loss may result. Each OLED B of the pixel 10 will typically age at the same pace, the aging effect will therefore not affect any relative output efficiency relation between the respective sub-pixels 101, 102, and 103 over time. The technical effect thereof is that the color balance will be more stable. While all three sub-pixels of pixel 10 are of the same size in FIG. 3, it is envisaged that the sub-pixels may be of different size. This is e.g. the case in standard OLED displays of the PenTile matrix type,

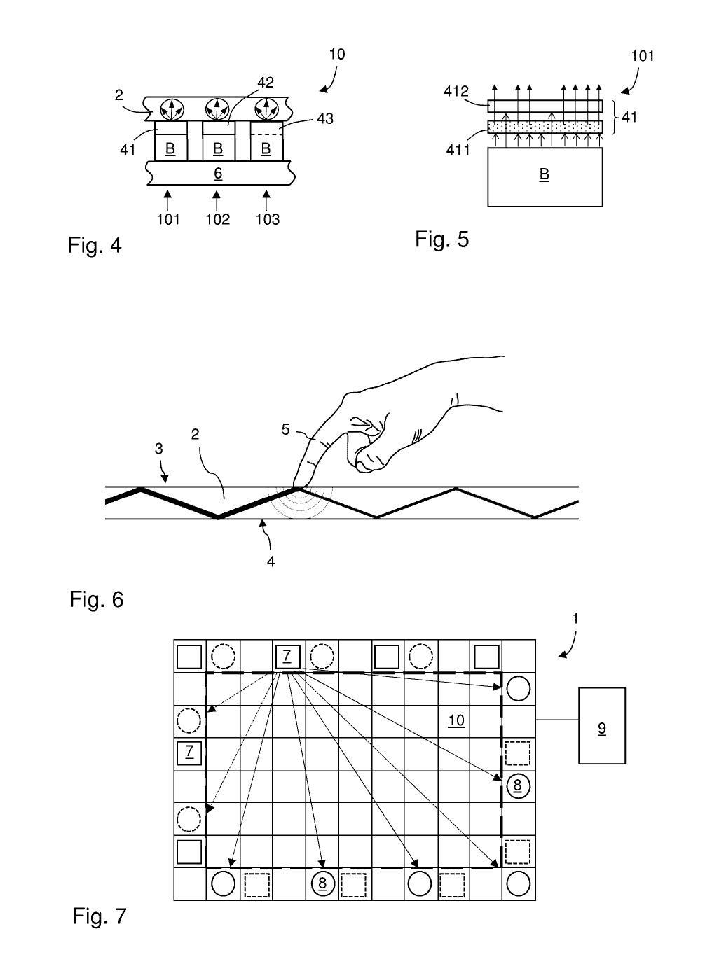

FIG. 4 shows a side sectional view of a pixel 10 of a display panel 1, with an embodiment of the pixel configuration of FIG. 3. Each OLED B is disposed on a backplane 6, and a front lens 2 is arranged over the OLEDs B. For the red and green sub-pixels, a respective QD structure 41 and 42 is disposed between the respective OLED B and the front lens 2. An additional bridging layer 43 may be disposed over or under the blue sub-pixel 103, so as to accommodate for the height difference resulting from the QD structures 41, 42. When placed over the blue sub-pixel 103, as in the drawing, this bridging layer 43 is preferably index matched between the OLED B and the front lens 2, so as to minimize reflections of light from the blue sub-pixel 103 in the lower surface 4 of the front lens 2.

FIG. 5 schematically illustrates a sub-pixel in accordance with the embodiment of FIGS. 3 and 4, in the example of the red sub-pixel 101. It should be noted, though, that the general conceptual layout of the QD structure described with reference to FIG. 5 is applicable to sub-pixels configured to emit light at any wavelength in accordance with the invention. The QD structure 41 is disposed over an OLED B configured to emit light at a base wavelength, e.g. blue. Furthermore, the QD structure 41 comprises a first layer 411, which is transparent to the wavelength of the light emitted from the OLED B over which it is disposed. This first layer contains quantum dots, selected so as to have the property to absorb light emitted from the underlying OLED B, and to emit light at a first longer wavelength, e.g. red light. The quantum dots may e.g. be suspended in a polymer film in layer 411. As an alternative, the first layer may be produced by means of e.g. ink jet printing or screen printing. As an example, “Tunable Infrared Emission From Printed Colloidal Quantum Dot/Polymer Composite Films”, published in Journal Of Display Technology, vol. 6, no. 3, March 2010, by Panzer et al. suggests providing a mixture of QDs and polyisobutylene (PIB) suspended in a mixture of hexane and octane as an ink to print an emissive layer on top of a substrate. A polymer matrix is then used to encapsulate and isolate the QDs from one another.

Since this is a red light sub-pixel 101, preferably no blue light should escape through the front lens 2. For this purpose, a second layer 412 is disposed over the first layer 411. The second layer 412 is transparent to light emitted by the quantum dots of layer 411, i.e. red, but substantially opaque to light emitted from the OLED over which the first layer 411 is disposed, i.e. blue. The second layer thus partially acts as a color filter, and may e.g. be provided by means of a multilayer dielectric film. It may be noted that the second layer 412 may not be included, if the absorption in the first layer 411 is sufficient to either completely eliminate any passing blue light, or such that any passing blue light will not have any negative influence on the color perceived by a user.

It may be noted that while the emission wavelength is quite narrow, quantum dot materials are generally absorptive to light within a wide wavelength range below the peak emission wavelength. Therefore, the QD structure may also absorb ambient light through the front lens 2, and thereby emit light through luminescence, which would represent unwanted light. In order to alleviate this effect, the second layer 412 should preferable be substantially opaque to all visible light just below the peak emission wavelength of the quantum dots of layer 411.

The effect provided by means of the layer 411 and 412 is schematically illustrated by means of arrows in FIG. 5A, where arrows with a simple line head indicate blue light, and arrows with a solid head indicate red light. It may be noted that normally not all light is completely vertical as shown in the drawing.

Exemplary QDs for use in the QD structures 41 and 42, i.e. quantum dots which absorb blue light and emit red or green light, may comprise e.g. CdSe or ZnS. Suitable QDs include core/shell luminescent nanocrystals comprising CdSe/ZnS, InP/ZnS, PbSe/PbS, CdSe/CdS, CdTe/CdS or CdTe/ZnS. The QDs may include an outer ligand coating and be dispersed in a polymeric matrix. As noted before, the size of the QD affects the wavelength of the emitted light. Hence, the QD layer 41 and the QD layer 42 may comprise quantum dots of the same material, such as one of the above-mentioned, but with different particle sizes. This is well known within the field of quantum dots, and will therefore not be exemplified in any greater detail herein. In an alternative embodiment, a different QD material may be used in the QD structure 41 than in the QD structure 42.

The preceding description passages have dealt with the general pixel configuration comprising an OLED and a QD structure, and a display panel built up of a plurality of RGB pixels, each comprising three sub-pixels 101, 102, and 103, which all include a blue OLED B. Additional embodiments will now be described, relating to a touch-sensitive display panel 1. More specifically, embodiments will be described, which provide a truly integrated optical touch-sensing display panel 1.

FIG. 6 illustrates the operating principle of an touch-sensing display panel. In the side view of FIG. 6, a beam of light is propagated by total internal reflection (TIR) inside a planar (two-dimensional) light guide 2. The light guide 2 comprises opposing surfaces 3, 4 which define a respective boundary surface of the light guide 2. Each boundary surface 3, 4 reflects light that impinges on the boundary surface from within the light guide 2 at an angle that exceeds the so-called critical angle, as is well-known to the skilled person. When an object 5 is brought sufficiently close to one of the boundary surfaces (here, the top surface 3), part of the beam may be scattered by the object 5, part of the beam may be absorbed by the object 5, and part of the beam may continue to propagate in the light guide by TIR in the incoming direction. Thus, when the object 5 touches the top surface 3, which forms a “touch surface”, the total internal reflection is frustrated and the energy of the transmitted light is decreased, as indicated by the thinned lines to the right of the object 5. This phenomenon is known as FTIR (Frustrated Total Internal Reflection) and a corresponding touch-sensing device may be referred to as an “FTIR system”. In preferred embodiments of the invention, the light guide 2 is the cover lens for the display pixels, as described above. Alternatively, the light guide may be provided as an extra optical layer 2 over the front lens. Generally, the light guide 2 may be made of any material that transmits a sufficient amount of radiation in the relevant wavelength range to permit a sensible measurement of transmitted energy. Such material includes glass, poly(methyl methacrylate) (PMMA), polycarbonates (PC), PET (poly(ethylene terephthalate)) and TAC (Triallyl cyanurate). It is possible that the light guide 2 is comprised of plural material layers, e.g. for the purpose of scratch-resistance, anti-fingerprint functionality, anti-reflection or other functional purpose.

Although not shown in FIG. 6, the FTIR system typically includes an arrangement of emitters and detectors, which are distributed along the peripheral region of the touch surface 3. Light from an emitter is introduced into the light guide 2 and propagates by TIR to one or more detectors. Each pair of an emitter and a detector defines a “detection line”, which corresponds to the propagation path from the emitter to the detector. Any object that touches the touch surface along the extent of the detection line will thus decrease or attenuate the amount of light received by the detector. The emitters and detectors are typically arranged to define a grid of intersecting detection lines on the touch surface, whereby each touching object is likely to cause an attenuation of several non-parallel detection lines. The arrangement of detectors is electrically connected to a signal processor, which acquires and processes an output signal from the arrangement. The output signal is indicative of the power of received light at each detector. The signal processor may be configured to process the output signal for extraction of touch data, such as a position (e.g. x, y coordinates), a shape or an area of each touching object.

Examples of touch systems based on FTIR are known in the art. U.S. Pat. No. 7,432,893, for instance, discloses a touch sensing system that uses FTIR to detect touching objects, in which light emitted by a light source is coupled into a transparent light guide by a prism. US20080150848 discloses an OLED display combined with touch sensor. In this disclosure, a separate waveguide in which infrared (IR) light propagates by TIR is placed over the display light guide, and throughout the surface of the display light guide, IR-sensing OLED elements are dispersed. Upon touching the waveguide, some light will be scattered downwards and detected by the underlying OLED sensor element. However, while FIG. 6 illustrates the working principle of FTIR touch as such, the invention relates to a touch-sensing display panel in which an FTIR touch-sensing mechanism is truly integrated with a display, as will be shown with reference to the subsequent drawings.

FIG. 7 is a top plan view of a touch-sensing display panel 1 according to an embodiment of the invention. The touch-sensing display panel 1 is implemented as a combination of a light transmissive light guide 2 that defines a front touch surface 3, and a dual-function display pixel matrix which is configured to both display images through the front surface 3 and provide touch sensitivity to the front surface 3 via FTIR. As seen in the plan view of FIG. 2A, a plurality of emitters 7 and detectors 8 are arranged in the peripheral region 11 of the display panel 1. Emitters 7 are indicated by squares and detectors 8 by circles, but this distinction is only made for the sake of simplicity and has no functional meaning. In the drawing, the emitters 7 and detectors 8 are arranged in an interleaved fashion in the peripheral region 11. It should be noted, though, that interleaved arrangement is merely one example of positioning the emitters 7 and detectors 8. Another example may be to arrange emitters along two sides, and detectors along the other two sides, of the panel 1 (which is indicated by some emitters 7 and some detectors 8 being drawn with dashed lines). Furthermore, a central region 12 of the panel 1 comprises a matrix of pixels 10, acting as image-forming elements or picture elements, that define a display area for displaying visual images in monochrome or color. A control unit 9 is connected to the pixels 10 of the display panel 1. This control unit 9 is also connected to the emitters 7 and detectors 8, for driving the touch-sensing system to detect touches on the front surface. It may be noted that the control unit 9 is a functional unit, and in reality different micro-processors and different software code may be employed for driving the image-forming pixels 10 and the touch-sensing system of emitters 7 and detectors 8.

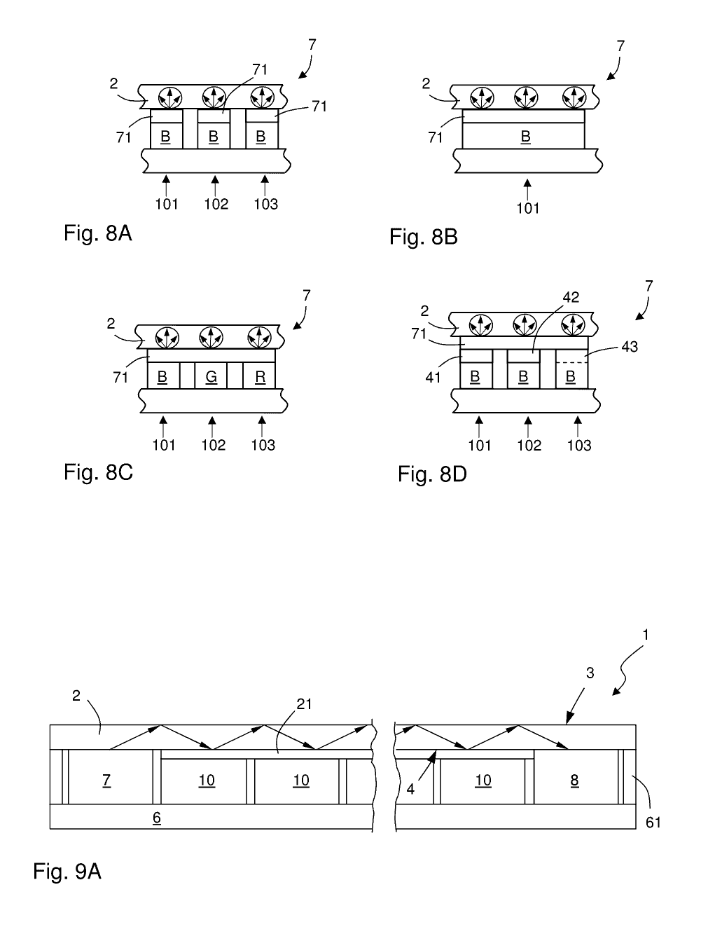

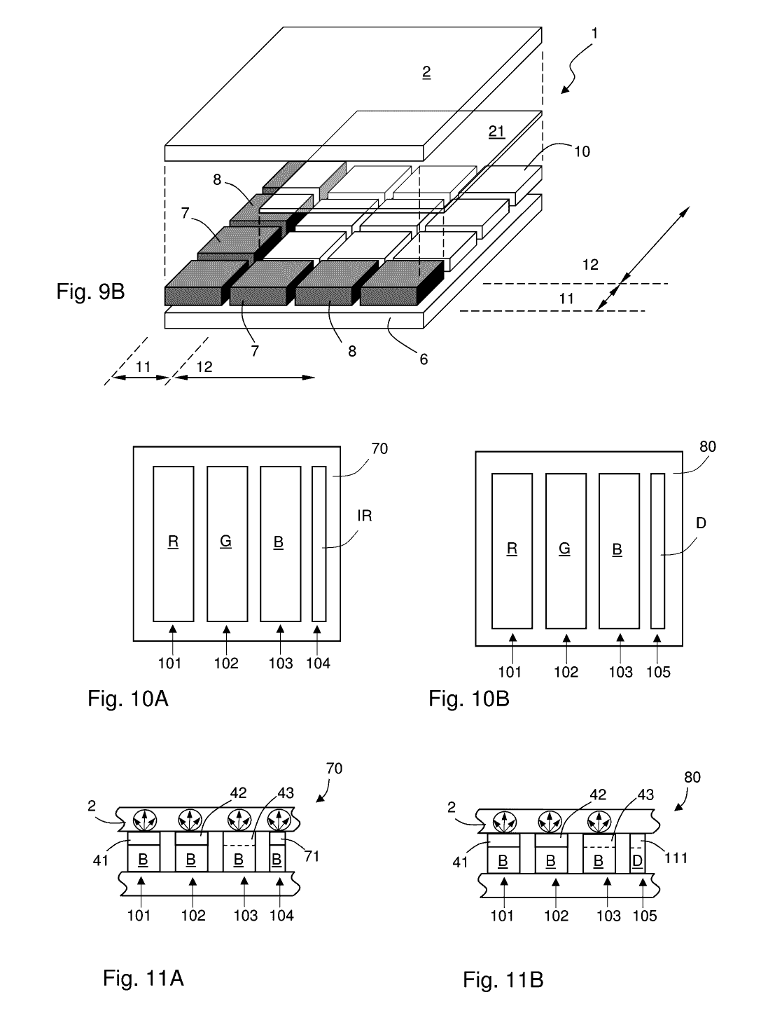

FIGS. 8A to 8D show a number of different embodiments of a pixel configured to act as an IR emitter 7. These are examples of embodiments of a pixel 7 for use in a peripheral region 11 of a display panel 1, which display panel 1 also comprises a plurality of image-forming pixels 10 in a central region 12, such as e.g. the display panel 1 of FIG. 7, or as shown in FIG. 9A and 9B, which schematically show a display panel 1 in a perspective view and in a side sectional view, respectively. In addition to the image-forming pixels 10, the display panel 1 further comprises a light guide 2 having a front surface 3 forming a touch-sensing region and an opposite rear surface 4 facing the pixels of the panel 1. In a display panel 1 having IR emitters 7 and detectors 8 arranged in the peripheral region 11, the touch-sensing region will substantially correspond to the central region 12, i.e. covering the pixels 10 inwardly of the peripheral pixel rows and columns where the emitters 7 and detectors 8 are disposed. The IR emitter 7 is optically connected to emit light into the light guide 2 for propagation therein through total internal reflection in at least the front surface. This light is subsequently coupled out to an IR detector 8 connected to receive propagated light from the light guide, as indicated in FIG. 7 and also in FIG. 9A. Those detectors 8 are configured to detect variations in received light in response to the front surface 3 being touched.

The depicted pixel in the embodiments of FIGS. 8A to 8D each have a first pixel configuration including a first sub-pixel 101, which first sub-pixel comprises a first OLED B configured to emit light at a base wavelength, and a first QD structure disposed over the first OLED B. The first QD structure is configured to absorb light of the base wavelength so as to emit infrared (IR) light, such that the first sub-pixel 101 is configured to act as an IR emitter 7. More specifically, in the embodiments of FIGS. 8A to 8D, the entire pixel 7 is configured to act as an IR emitter.

FIG. 8A shows a pixel comprising a first sub-pixel 101, a second sub-pixel 102, and a third sub-pixel 103. Each one of those three sub-pixels comprises an OLED B configured to emit blue light. Furthermore, the pixel comprises a first quantum dot structure 71 arranged over the OLEDs of the first 101, second 102 and third sub-pixels. This first quantum dot structure 71 is configured to absorb blue light so as to emit IR light, such that the entire at least one pixel is configured to act as an IR emitter 7. In the drawing, the first quantum dot structure 71 is drawn as comprising separate parts arranged over the respective sub-pixel OLED. In an alternative embodiment, the first quantum dot structure 71 need not be divided in this way, but may instead comprise a single layer disposed over all the sub-pixels 101, 102, 103 of the IR emitter pixel 7, similar to the arrangement of FIG. 8C. The IR emitter pixel 7 of FIG. 8A is suitable for use in a display panel 1, in which the image-forming pixels 10 are configured in accordance with FIGS. 3 and 4. This way, a touch-sensing display panel 1 may be obtained, in which all pixels of the display panel 1 may be manufactured in substantially the same process. More specifically, all OLEDs B may be of the same blue type. As noted with reference to FIG. 3, the sub-pixels of one pixel may be of different size, if larger sub-pixels are desired for certain colors, but each pixel may nevertheless be identical. It will only be the type of QD structure 41, 42, 71 added (or not added for a blue sub-pixel) on the respective OLEDs B that will decide if the pixel will be an image-forming pixel 10 configured to emit visible light, or an IR pixel 7.

FIG. 8B shows an alternative embodiment of an IR pixel 7. In this embodiment, one single OLED B is included in the pixel 7, as the sole sub-pixel 101, and the IR emitter 7 will thus not be identical to the image-forming pixels 10, in terms of OLED structure. However, the structure of the IR pixel 7 is simpler and may require fewer connectors, which may render lower manufacturing cost.

FIG. 8C shows a drawing of another embodiment of an IR pixel 7. As noted above, the first QD structure 71 is in this embodiment configured to cover all three sub-pixels 101, 102, 103 of the pixel 7. In an alternative arrangement of the embodiment of FIG. 8C, the first QD structure 71 may be divided as in this example of FIG. 8A. In the embodiment of FIG. 8C, the IR pixel 7 is created by means of the QD structure 71, disposed on an RGB OLED pixel. More specifically, the pixel 7 comprises a first sub-pixel 101 including an OLED B configured to emit blue light, a second sub-pixel 102 including an OLED G configured to emit green light, and a third sub-pixel 103 including an OLED R configured to emit red light. The quantum dot structure 71 is arranged over the first, second and third sub-pixels and configured to absorb visible light so as to emit infrared light. This way, the entire pixel 7 is configured to act as an IR emitter 7. The IR emitter of FIG. 8C may be used in conjunction with a display panel 1 with image-forming pixels arranged in accordance with FIG. 3. However, the pixel configuration of the embodiment of FIG. 8C is more suitable for use in a display panel 1, in which the image-forming pixels 10 are configured as RGB OLEDs, e.g. as in FIG. 2. This way, a touch-sensing display panel 1 may be obtained, in which all pixels of the display panel 1 may be manufactured in substantially the same process, since the pixel configuration of the image-forming pixels 10 and the IR emitter pixels 7 may be the same for the OLED structures. As noted before, the sub-pixels 101, 102, 103 of one pixel may be of different size, if larger sub-pixels are desired for certain colors, but each pixel may nevertheless be identical on the OLED level. It will only be the QD structure 71 added on the respective RGB OLEDs that will create an IR emitter pixel 7 from an image-forming pixel 10.

FIG. 8D shows a drawing of an embodiment of an IR emitter 7, which is suitable for use in a display panel 1 having image-forming pixels 10 configured in accordance with FIGS. 3 and 4, i.e. pixels having all blue OLED sub-pixels 101, 102, 103, which are configured to act as an RGB pixel by means of the QD structures 41 and 42. The IR emitter 7 is obtained by providing a second QD structure 71 on top of all sub-pixels 101, 102, 103, which second QD structure 71 is configured to absorb visible light so as to emit infrared light. Again, this allows for a touch-sensing display panel 1 to be obtained, in which all pixels of the display panel 1 may be manufactured in substantially the same process. More specifically, all OLEDs B may be of the same blue type, and a repeated QD structure layer 41, 43 for creating RGB pixels can be applied throughout the panel 1. Only the addition of the second QD structure 71 turns an RGB pixel 10 into an IR emitter pixel 7.

In the embodiments of FIGS. 8A, 8C, and 8D, the control unit 9, as seen in FIG. 7, is preferably configured to drive the first 101, second 102 and third 103 sub-pixels together, so as to act together as an IR emitter 7. This will provide more light emitted at one time from one IR emitter pixel 7, and consequently a potentially stronger maximum optical signal at the respective detector 8. Depending on implementation, the different emitters 7 as illustrated in FIG. 7, may be activated in sequence or concurrently, e.g. by implementing the coding scheme disclosed in WO2010/064983. As noted with reference to FIG. 7, the IR emitter pixels 7 are preferably arranged in the peripheral region 11 along at least one edge of the display panel 1, surrounding a central region 12 of the display panel 1. By integrating the emitters/detectors 7, 8 at the peripheral region 11 of the display panel 1, it is possible to omit separate contacting of the emitters/detectors 7, 8. Instead, they may be contacted and electronically controlled in the same way as the pixels 10. For example, a data bus structure or an electronics backplane for supplying control signals to the pixels 10, to selectively control the light emitted by the pixels 10, may also be used to supply control signals to the individual emitters 7 and detectors 8 and/or to retrieve output signals from the individual detectors 8. A cover frame (not shown), opaque to visible light, may furthermore be provided over the peripheral region 11. Such a cover frame may serve the purpose of covering the emitter 7 and detector 9 structures, so as not clutter he appearance for a user of the display panel 1. In addition, the cover frame may be reflective to IR light, thus protecting the detectors from direct incident ambient light, so as to improve the signal to noise ratio of IR light sensed by the detectors 8.

From the known characteristics of quantum dots, it will be understood that when excited by light from the underlying OLED (or QD structure as in FIG. 8D), the QD structure 71 will emit fluorescent light, of which at least a part will impinge on and be injected into the light guide 2, as indicated by the encircled arrows directed up from the first QD structure 71. As already outlined with reference to FIG. 4, there may be different ways of realizing the first QD structure 71. Different possible QD materials non-exhaustively include PbSe, PbS/CdS core/shell, InAs, InAs/InP/ZnSe core/shell/shell etc. Another example may be taken from the article “Near-infrared emitting CdTe0.5Se0.5/Cd0.5Zn0.5S quantum dots: synthesis and bright luminescence”, Nanoscale Research Letters 2012, 7:615, in which Yang et al. give examples related to synthesis of NIR-emitting QDs in the 700-900 nm range. They created hydrophobic core/shell QDs of the kind identified in the article title, with tunable photoluminescence between green and near-infrared, with a maximum peak wavelength of 735 nm with an average diameter of the QDs at 6.1 nm. It will thus be realized that numerous different examples of QD materials can be found in the art. In one embodiment, the material and particle size of the first QD structure 71 is responsive to emit Near Infrared (NIR) light, i.e. above 700 nm, responsive to absorption of blue light. Due to the nature of quantum dots, a certain composition of quantum dots, in terms of particle size and material, may absorb light throughout the visible wavelength range, but emit light at one peak wavelength, such as the CdTe0.5Se0.5/Cd0.5Zn0.5S QDs of the aforementioned Nanoscale Research Letters article. This is beneficial for embodiments such as those of FIG. 8C and 8D, where RGB light pumps the QD structure 71. Furthermore, different means for suspending the QDs in the structure 71 may be used. In one example, the QDs may be suspended in a polymer film as a carrier material, such as in the Nanosys QDEF. Another example may be to provide QDs in an ink solution, which is printed on a substrate, which is then encapsulated, as mentioned above with reference to the Panzer article. In any situation, the skilled person would realize that there are many ways of putting the QD structure 71 into practice.

FIG. 9A schematically illustrates a side sectional view of an embodiment of the display panel 1, with separate pixel elements 10 indicated at the central region of the panel. As is well known in the art, each pixel 10 may be configured to emit light in one color only, or may comprise several sub pixels configured to emit light in different colors, such as RGB. Each pixel 10 may include one or several OLEDs. The leftmost pixel is denoted as an IR emitter pixel 7. As such, the IR emitter pixel 7 may comprise one IR-emitting sub-pixel 101. Alternatively, the IR emitter pixel 7 may include a plurality of sub-pixels configured to be driven collectively as one IR emitter 7. A detector 8 is arranged at the opposite end of the cross-section of the panel 1, for receiving light propagating from the emitter 7 by TIR in the light guide 2. The detector 8 may e.g. be a photo detector. As is well known, OLEDs are sensitive to moisture, and the organic layers must therefore be encapsulated. Apart from the light guide 2 and the bottom sheet 6, a hermetic peripheral seal 61 is therefore also provided on the panel, e.g. by means of a UV-curable epoxy.

Preferably, as already described, also the emitter 7 comprises OLEDs formed integrally with the image-forming pixels 10. However, the purposive use of the emitter 7 on the one hand, and the image-forming pixel elements 10 on the other hand, are quite different. The image-forming pixels 10, i.e. the display pixels, are configured to shine light out from the display panel 1, preferably in a wide cone angle but most importantly straight up (in the drawing), which would normally represent the best viewing angle for an observer. The emitter 7, however, will only be useful if its light is captured within the light guide 2 to propagate with TIR towards the detector 8. As a consequence, the part of the light emanating from the emitter 7 that goes straight up will be lost. However, a certain part of the light will impinge on the front surface 3, from the inside of the light guide 2, in a wide enough angle to be deflected by TIR.

A quantum dot material is not a reflector, but a material that absorbs and emits light. As such, it does not repeat or reflect the angle of light received. Rather, each quantum dot acts as a new emitting dot, capable of emitting photons at various directions. Parts of the light emitted by the first QD structure 71 upon excitation from the underlying OLED will be coupled into the light guide 2 at an angle suitable for FTIR purposes, so as to subsequently propagate therein and be coupled out to a detector 8 at another portion of the peripheral region 11. In this sense, the first QD structure 71 may act as a diffuser in the peripheral region 11. Suitable angular ranges for FTIR purposes will in part be determined by Snell's law and the relation between indices of refraction between the light guide 2 and its neighboring optical layers facing the front surface 3 and rear surface 4. One benefit of employing a QD structure 71 to emulate the emitter 7 is that the QD structure may emit light in very wide angles, which is purposeful for FTIR. In “Electromagnetic Modeling of Outcoupling Efficiency and Light Emission In Near-Infrared Quantum Dot Light Emitting Devices”, published in Progress In Electromagnetics Research B, Vol. 24, 263-284, 2010, A. E. Farghal, S. Wageh, and A. A. El-Azm report an analytical exciton emission model for simulating the radiation characteristics of near-infrared Quantum Dot-light emitting devices (QD-LED). More specifically, their results show the angular radiation profile for such a QD-LED disposed on a glass substrate, from which it is clear that most of the radiation from vertical exciton is emitted above the critical angle (41.8±) and thus cannot escape from the glass substrate into the air. The vertical oriented exiton is substantially toroidal in shape, which is a definite advantage for an FTIR emitter.

One problem may be related to the fact that the refractive index of the image-forming pixels 10 may be higher than the index of the light guide 2. In such a scenario, light may escape downwards through the pixels 10 after reflection in the front surface 3. In one embodiment, measures for assuring that light injected from the emitters 7 will propagate by TIR over the central region 13 include configuring the QD structure 71 to have a higher refractive index than the image-forming pixels 10 disposed in the central region 12. This may e.g. be obtained by selective doping of a carrying material of the QD structure 71, or by selection of a suitable polymer matrix material for carrying the quantum dots in the QD structure 71.

In an alternative embodiment, an optical layer 21 may be disposed between the rear surface 4 of the light guide 2 and the image-forming pixels 10, for the purpose of promoting TIR in the rear surface 4 of the light guide 2. In one embodiment, where the refractive index of the light guide 2 is n₀, the optical layer 21 is made from a material which has a refractive index n₁, which is lower than n₀. That way, there will be TIR in the light guide 2 in both the front surface 3 and the rear surface 4, as indicated by the arrows in FIG. 9A, provided that the angle of incidence is wide enough. As an example, the optical layer 21 may be provided by means of a resin used as a cladding material for optical fibers. Such a resin layer may be provided on the substrate 2 before deposition of the electrode and organic layers. Alternatively, if the OLED structure is built from a bottom sheet or plate 9, the optical layer 21 may be provided on the lower face 4 of the light guide 2 before attachment over the pixels 7, 8, 10, or over the pixels before attachment of the light guide 2. Another example of an optical layer 21 with a lower refractive index is an air gap 21.

In another embodiment, the optical layer 21 is a wavelength-dependent reflector. Particularly, reflection of the emitter light in the rear surface 4 is obtained by providing an optical layer 21 which is at least partly reflective for the emitter light, while at the same time being highly transmissive for visible light. As an example, such an optical layer 21 may be provided by means of a commercially available coating called IR Blocker 90 by JDSU. This coating 21 has a reflectivity of up to 90% in the NIR, while at the same time being designed to minimize the effect on light in the visible (VIS) range to not degrade the display performance of the touch system, and offers a transmission of more than 95% in the VIS. It should be noted that there are also other usable available types of coatings, IR Blocker 90 being mentioned merely as an example. This type of wavelength-dependent reflectors are typically formed by means of multi-layer coatings, as is well known in the art. In an embodiment of this kind, light from the emitters 7 will propagate by TIR in the front surface 3 and by partial specular reflection in the rear surface 4.

It should be noted that the drawings here do not represent any realistic scale. The thickness of the light guide front glass 2 may be dependent on the size of the panel 1 and what it intended to be used for, i.e. the environment it will be used in. However, an OLED structure as such, with electrode layers and intermediate organic layers, may be very thin and even less than 1 μm. The substrate 2 or 6 and the cover 6 or 2 will add to the thickness considerably, though, in order to provide rigidity to a certain extent. In one embodiment, the light guide may be in the order of 200-500 μm thick. The optical layer 21, though, need not be thicker than 1-5 μm to provide the cladding effect of realizing TIR in the rear surface 4 of the light guide 2.

FIG. 9B shows quite schematically a corner portion of the touch-sensing display panel 1 of FIG. 9A. For the sake of simplicity, the peripheral seal 61 is left out in this drawing. The lower left corner in the drawing represents an outer corner of the panel 1, whereas the right and upper edges are to be understood as cutout from a larger panel 1. Emitters 7 and detectors 8, shown in grey, are arranged along the peripheral region 11, and the optical layer 21 is provided to cover the central region 12 of the panel 1 and the image-forming pixels 10 arranged at the central region 12. In an alternative embodiment (as can be seen in FIG. 7), image-forming pixels 10 are also present in the peripheral region 11 among the emitters 7 and detectors 8. Also, the peripheral region 11 may comprise more than one row of pixels. In addition, the optical layer 21 may cover also such image-forming pixel elements 10 provided in the peripheral region 11, in addition to covering the central region 12. It should be understood that FIG. 9B only schematically shows the different elements in a separated manner in order to clearly point out those elements, it shall not to be understood as an assembly instruction or the like.

While FIGS. 9A and 9B only indicate an optical layer at the central region 12, this optical layer 21 may have an extension portion (not shown) provided over the emitters 7 and detectors 8. Such an extension portion 21a preferably has substantially the same thickness as the optical layer 21, which will make it easier to make produce the OLEDs in the peripheral region 11 and in the central region 12 in the same process, since they will be provided at the same level. Preferably this extension portion has a refractive index n₂ which is higher than the refractive index n₁ of the optical layer 21. This way, light that is injected into the light guide 2 through the extension portion may still be reflected in the rear surface 4 where it faces the optical layer 21, provided that the angle of incidence is large enough. The refractive index n₂ of the extension portion may e.g. be the same as the refractive index n₀ for the light guide 2. Alternatively, a material for the extension portion may be chosen such that its refractive index lies between the refractive index for the light guide 2 and the refractive index for the emitter 7 and/or the detector 8.

FIG. 10A illustrates another embodiment of a pixel configured to act as an IR emitter 70. Rather than being an all IR emitting pixel, as the pixels 7 described with reference to FIGS. 8A to 8D, the IR-emitting pixel 70 is configured to emit both RGB and IR, through respective sub-pixels 101, 102, 103, 104. The pixel 70 is configured for use in a display panel 1 having a plurality of pixels 10, and the pixel 70 has a pixel configuration with a first sub-pixel 101 comprising a first OLED B configured to emit blue light, and a first quantum dot structure 41 disposed over the first OLED B and configured to absorb blue light so as to emit red light. The pixel 70 further includes a second sub-pixel 102, which comprises a second OLED B configured to emit blue light, and a second quantum dot structure 42 disposed over the second OLED, configured to absorb blue light so as to emit green light, and a third sub-pixel 103, which comprises a third OLED B configured to emit blue light. In this respect, the first 101, second 102, and third 103 sub-pixels may functionally correspond to the sub-pixels described with reference to FIGS. 3 and 4. In addition thereto, the pixel comprises a sub-pixel 104 configured to act as said IR emitter, which comprises a fourth OLED B configured to emit blue light, and a third quantum dot structure 71 disposed over the fourth OLED. The third quantum dot structure 71 may be configured to absorb blue light so as to emit infrared light. In this context, the sub-pixel 104 may be configured in a corresponding manner as the IR-emitting sub-pixels of FIG. 8A. The pixel 70 of FIG. 10A is configured for use in a display panel 1, which comprises a light guide 2 having a front surface 3 forming a touch-sensing region and an opposite rear surface 4, wherein the IR emitter is optically connected to emit light into the light guide for propagation therein through total internal reflection in at least the front surface. Furthermore, an IR detector 8 is connected to receive propagated light from the light guide. The pixel 70, acting as IR emitter, may thus be used in substitution for the IR emitter 7, in the embodiments described with reference to FIG. 7 and FIGS. 9A and 9B.

FIG. 11A shows a side sectional view of the pixel configuration of pixel 70. As can be seen, three RGB sub-pixels 101, 102, and 103 are configured in the manner described with reference to FIG. 4, whereas the IR sub-pixel 104 is configured in the manner described with reference to e.g. FIG. 8A. As noted before, the sub-pixels 101, 102, and 103 need not be equally large. In a preferred embodiment, though, the IR sub-pixel 104 is smaller than the RGB sub-pixels 101, 102, and 103, respectively. This way, an IR emitter 70 may be obtained while still accommodating the major part of the pixel 70 for visible light, so as to provide a satisfactory display quality. In one embodiment, a plurality of adjacent pixels 70 are driven concurrently, so as to emulate a larger IR emitter. This way more IR light may be obtained from the (emulated) IR emitter. The requirements set on touch resolution together with the pixel pitch may determine how many pixels 70 may be grouped together and driven as one, by the controller 9.

FIGS. 10B and 11B illustrate an IR-detecting pixel 80, which may be included in the display panel 1, similar to the IR-emitting pixel 70. In this pixel configuration, the RGB pixels 101, 102, and 103 may be correspond entirely to those of FIG. 10A and 11A. Thus, the IR-detecting pixel 80 may operate as an RGB pixel corresponding to what was described with reference to reference to FIGS. 3 and 4. In addition, the pixel 80 includes a sub-pixel 105 configured to act as an IR detector D. The detector D may e.g. be a photo detector. The sub-pixel 105 may also comprise a layer 111, which may comprise a band pass filter for the wavelength of interest, i.e. the peak emission wavelength of the IR-emitting QD structure 71 of an IR emitter 7 or 70 in the display panel 1. The layer 111 may also comprise a coupling structure, such as a diffusive surface area, at the rear surface 4 of the light guide 2, so as to promote out-coupling of propagated light to the detector D. As for the IR-emitting pixel 70, the detector sub-pixel 105 is preferably smaller than the RGB sub-pixels 101, 102, and 103, respectively. In one embodiment, a plurality of adjacent pixels 80 are read concurrently, so as to emulate a larger IR detector. Again, the requirements set on touch resolution together with the pixel pitch may determine how many pixels 80 may be grouped together and read as one, by the controller 9. The IR-detecting pixel 80 may be used in substitution for detector 8 in an embodiment according to FIG. 7 or FIGS. 9A and 9B.

The pixels 70 and 80 may be identical with respect to the RGB sub-pixels 101, 102, and 103, wherein the pixel 70 may be said to be of a first sub-type pixel configuration, including an IR emitter, whereas the pixel 80 is of a second sub-type pixel configuration, including an IR detector.

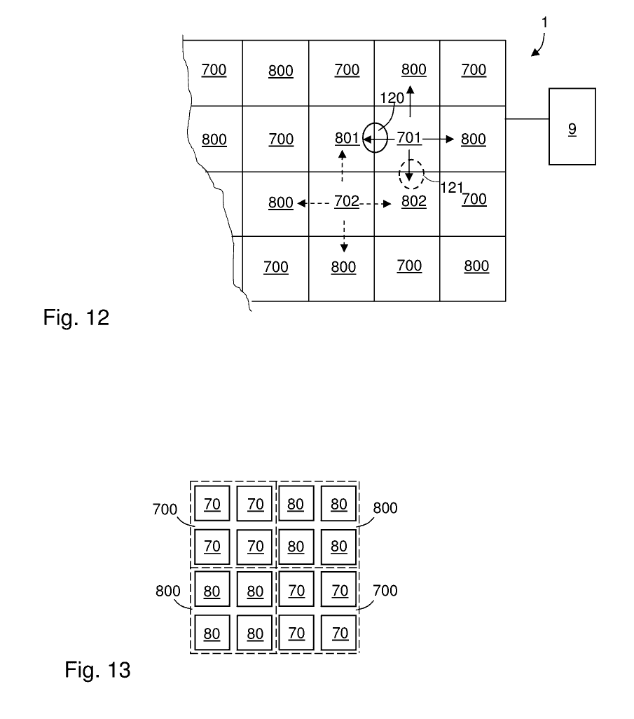

FIG. 12 schematically illustrates a corner portion of a display panel 1, according to an embodiment which differs from the embodiment of FIG. 7. In this embodiment, which also relates to an optical touch-sensing display panel 1, IR-emitting pixels are disposed over a touch-sensing region, sequentially with IR-detecting pixels 80, rather than being isolated to the peripheral region 11. FIG. 12 illustrates first type blocks 700, 701, 702 arranged in interleaved fashion with second type blocks 800, 801, 802. Each firth type block 700/701/702 includes one or more IR-emitting pixels 70 of said first sub-type 70, and are preferably substantially identical. Furthermore, each second type blocks 800/801/802 includes of one or more pixels of said second sub-type 80, and are also preferably substantially identical. Reference numerals 701/702 and 801/802 are merely chosen to indicate particular blocks from the plurality of first type blocks 700 and second type blocks, respectively. The first type of group 700 may include more than, fewer than, or as many pixels 70 as the number of pixels 80 included in the second type of group 800. Also, each group 700/800 may comprise only one pixel 70/80 each.

FIG. 13 schematically illustrates an embodiment of a portion of the display panel 1 of FIG. 12. In this embodiment, four pixel blocks 700, 800 are shown. Each first type block 700 includes four IR-emitting pixels 70, and each second type block 800 includes four IR-detecting pixels 80. In the shown embodiment the included pixels 70/80 of the respective block 700/800 are arranged in a square configuration, but alternative arrangements are plausible.

Reverting to FIG. 12, it may be understood that at least a part of the light injected into the light guide 2 from the IR-emitting sub-pixel 104, at wide angles, will TR in the front surface 3. However, when reflected light hits the lower surface, it may be coupled out. If the light is coupled out at a sub-pixel 105, it will be sensed by detector D, and variations in the sensed light may be interpreted in controller 9 as frustration of the optical signal, indicating a touch on the front surface 3, as earlier described. If coupled out at other sub-pixels 101, 102, 103, 104, the light will be lost. Since each IR emitter 104 in the embodiment of FIG. 10A is substantially smaller than in any of the embodiments of FIG. 8A-8D, and also due to the fact that light will leak out in every reflection at the lower surface 4, light will not propagate as efficiently in light guide 2 as in an embodiment according to the general principles of FIGS. 7-9. In fact, in its simplest form, light will only be reflected once in the front surface 3, between injection into and coupling out from the light guide. The propagation length will be dependent on a number of factors, including the relation of refractive indices of the light guide 2 and the IR-emitting sub-pixel 104 and the thickness of the light guide 2, as will be readily understood by the skilled person. As an example, for light impinging at a 70 degree angle towards the front surface 3 in a light guide 2 which is 500 μm thick, the propagation length in the plane of the light guide 2 may be less than 3 mm. By proper setting of a detection threshold of detectors D in sub-pixels 105, light emanating from IR emitters 104 located more than a certain distance, a detection range, from a respective detector D will not exceed the threshold level. The control unit 9 may in such an embodiment be configured to drive the IR emitters 104 sequentially, such that any two emitters 104 closer than twice the detection range will not be activated simultaneously. In addition, the controller may be devised to read out light sensed from detectors D sequentially, such that any variation in sensed light conditions by one or more detectors D will be uniquely linked to a certain IR emitter 104. This is schematically indicated in FIG. 12. If the pixel block 701 (comprising one or more pixels 70) is activated so as to emit light indicated by the solid arrows concurrently with one or more of its neighboring detectors, and a variation of the sensed optical signal is detected in block 801, it may be concluded by control unit 9 that a touch may have occurred at the area of the solid line circle 120. On the other hand, if a variation of the sensed optical signal is detected in block 808, it may be concluded by control unit 9 that a touch may have occurred at the area of the dashed line circle 121. The skilled person will realize that there are numerous ways of executing different types of sequences that will fulfill the object of determining the area of touch in a display device 1 according to this embodiment. This way, a fine resolution touch-sensing display device may be obtained. Since the propagation length is very small, very limited irradiance may be required from each emitter 104, which in turn means that they can be made very small in relation to the image-forming pixels 101, 102, 103.

Dependent on the configuration, particularly the thickness of the light guide 2, light may only travel one pixel, from an IR emitter pixel 70 to a neighboring IR detector pixel 80. However, for longer propagation paths, control unit 9 may be configured to drive a plurality of pixels 70 in one first block 700 as one common IR emitter, which may increase the amount of light emitted from each IR emitter 700. On the other hand, it will also increase the area of the emitter 700, and thus the possibility that light injected into the light guide 2 from one pixel 70 is coupled out through an IR emitter 104 of another pixel 70 of the same block 700 of pixels 70. Accordingly, touch-sensing will be most efficient at close distances between an IR-emitting pixel 70 and an IR-detecting pixel 80.

In one variant of the embodiment of FIGS. 12-13, this embodiment is based on the notion that each IR emitter pixel 70 comprises both image-forming RGB sub-pixels 101, 102, 103, and an IR-emitting sub-pixel 104. In a preferred embodiment, the IR-emitting sub-pixel 104 is configured to have a higher refractive index, at its interface to the light guide 2, than the other sub-pixels 101, 102, 103 of the pixel configuration. Correspondingly, each IR detector pixel 80 comprises both image-forming RGB sub-pixels 101, 102, 103, and an IR-detecting sub-pixel 105, wherein the IR-detecting sub-pixel 105 is configured to have a higher refractive index, at its interface to the light guide 2, than the other sub-pixels 101, 102, 103 of the pixel configuration. A selected refractive index may be obtained by careful configuration of the IR-emitting QD structure 71 and layer 111, e.g. by doping or selection of carrier, or bulk, material of the first QD structure. As a consequence, at least a part of the light injected into the light guide 2 from the IR-emitting sub-pixel 104, at wide angles, will not escape down through the image-forming sub-pixels 101, 102, 103 after TIR in the front surface 3, but will actually TIR also in the lower surface 4. However, where light hits a sub-pixel 104 or 105 after TIR in the front surface 3, light will be coupled out. If the light is coupled out at a sub-pixel 105, it will be sensed by detector D, and variations in the sensed light may be interpreted in controller 9 as frustration of the optical signal, indicating a touch on the front surface 3, as earlier described. However, light reflected in the rear surface 4 may continue to TR in the front surface 3 and reach another detector D of another IR-detecting pixel 80. This way, more detectors may be used to calculate the position of the assumed touch, based on the sensed amount of light and their positions relative to the activated IR emitter 70. By using a tomograph, e.g. following the principles of WO2009/077962, which is hereby incorporated by reference, the touch position may be calculated.

It is to be understood that the display apparatus/display unity may form part of any form of electronic device, including but not limited to a laptop computer, an all-in-one computer, a handheld computer, a mobile terminal, a tablet, a gaming console, a television set, etc. While the invention has been described in connection with what is presently considered to be the most practical and preferred embodiments, it is to be understood that the invention is not limited to the disclosed embodiments, but on the contrary, is intended to cover various modifications and equivalent arrangements included within the scope of the appended claims. It should be noted that while certain features have been described in conjunction with different drawings, such features may well be combined in one and the same embodiment.

1. A display panel comprising:
a plurality of pixels, including at least one pixel of a first pixel configuration with a first sub-pixel, which
the first sub-pixel comprising:
a first organic light emitting diode (“OLED”) configured to emit light at a base wavelength, and
a first quantum dot structure disposed over the first OLED and configured to absorb the emitted light of the base wavelength and emit light at a first wavelength longer than the base wavelength.

2. The display panel of claim 1, wherein the first OLED is configured to emit blue light and light at said first wavelength is red, said first pixel configuration further including a second sub-pixel, which comprises:
a second OLED configured to emit blue light, and
a second quantum dot structure disposed over the second OLED, configured to absorb blue light and emit green light; and a third sub-pixel, which comprises a third OLED configured to emit blue light.

3. The display panel of claim 2, further comprising:
an IR emitter;
a light guide having a front surface forming a touch-sensing region and an opposite rear surface facing the pixels, wherein said IR emitter is optically connected to emit light into the light guide for propagation therein through total internal reflection in at least the front surface; and
an IR detector connected to receive propagated light from the light guide.

4. The display panel of claim 3, wherein said first pixel configuration further includes a sub-pixel configured to act as said IR emitter, which comprises:
a fourth OLED configured to emit blue light, and
a third quantum dot structure disposed over the fourth OLED, configured to absorb blue light so as to emit infrared light.

5. The display panel of claim 3, wherein a first sub-type of said first pixel configuration includes a sub-pixel configured to act as said IR emitter, which comprises:
a fourth OLED configured to emit blue light, and
a third quantum dot structure disposed over the fourth OLED, configured to absorb blue light so as to emit infrared light; and
wherein a second sub-type of said first pixel configuration includes a sub-pixel configured to act as said IR detector.

6. The display panel of claim 1, wherein light at said first wavelength is infrared such that said first sub-pixel is configured to act as an IR emitter, the display panel further comprising:
a light guide having a front surface forming a touch-sensing region and an opposite rear surface facing the pixels, wherein said IR emitter is optically connected to emit light into the light guide for propagation therein through total internal reflection in at least the front surface; and
an IR detector connected to receive propagated light from the light guide.

7. The display panel of claim 6, wherein the first OLED is configured to emit blue light, and said first pixel configuration further comprises:
a second sub-pixel including a second OLED configured to emit blue light;
a third sub-pixel including a third OLED configured to emit blue light;
wherein said first quantum dot structure is arranged over the first, second and third OLEDs and configured to absorb blue light so as to emit infrared light, such that the entire at least one pixel is configured to act as an IR emitter.

8. The display panel of claim 6, wherein the first OLED is configured to emit blue light, and said first pixel configuration further comprises:
a second sub-pixel including an OLED configured to emit green light;
a third sub-pixel including an OLED configured to emit red light; wherein said first quantum dot structure is arranged over the first, second and third sub-pixels and configured to absorb visible light so as to emit infrared light, such that the entire at least one pixel is configured to act as an IR emitter.

9. The display panel of claim 7, comprising a control unit, configured to drive the first, second and third sub-pixels together, so as to act together as an IR emitter 7.

10. The display panel of claim 6, wherein said first sub-pixel is the only sub-pixel of said first pixel configuration.

11. The display panel of claim 3, wherein a number of pixels of the first pixel configuration are arranged in a peripheral region along at least one edge of the display panel, surrounding a central region of the display panel.

12. The display panel of claim 11, comprising
an optical layer disposed at the rear surface of the light guide to cover the central region, wherein said optical layer is configured to reflect at least a part of the propagating light impinging thereon from within the light guide.

13. The display panel of claim 11, wherein said quantum dot structure configured to emit IR light is configured to have a higher refractive index than pixels disposed in the central region.

14. The display panel of claim 5, wherein a number of first type blocks, each including of one or more pixels of said first sub-type, are sequentially arranged with a number of second type blocks, each including of one or more pixels of said second sub-type, over said touch-sensing region.

15. The display panel of claim 14, wherein said IR emitter and said IR detector are configured to have higher refractive indices than the other sub-pixels of the respective pixel configuration.

16. The display panel of claim 14, comprising a control unit, configured to drive the IR emitters of a first type block in synchronicity with the IR detectors of an adjacent second type block.

17. The display panel of any of claim 14, comprising a control unit, configured to drive a plurality of pixels in one first block as one common IR emitter.

18. The display panel of claim 1, wherein each quantum dot structure comprises:
a first layer, which is transparent to the wavelength of the light emitted from the OLED over which it is disposed, containing quantum dots; and
a second layer, disposed over the first layer, which is transparent to light emitted by said quantum dots but substantially opaque to light emitted from the OLED over which the first layer is disposed.
